(19) United States
(12) Patent Application Publication
(10) Pub. No.: US 2026/0213125 A1
(43) Pub. Date: Jul. 23, 2026

(54) Sample Processing Method and Charged Particle Beam Device

(71) Applicant: HITACHI HIGH-TECH CORPORATION, Minato-ku, Tokyo (JP)

(72) Inventors: Naoko HIROSE, Tokyo (JP); Hiroyuki MUTO, Tokyo (JP); Yasuhiko SUGIYAMA, Tokyo (JP)

(21) Appl. No.: 19/143,033

(22) PCT Filed: Dec. 27, 2022
(86) PCT No.: PCT/JP2022/048283

§ 371 Date: Jun. 25, 2025

(51) Int. Cl. H01J 37/302

(52) U.S. Cl. CPC H01J 37/3023

(57) ABSTRACT

Even when an acquired observation image has low quality, a boundary of a processing area of a sample is recognized, and the sample is processed after an irradiation position of a charged particle beam is adjusted such that a boundary portion of the charged particle beam comes into contact with a specified boundary of the processing area. A sample processing method includes: (S1) acquiring charged particle beam information including information on a shape and a size of a charged particle beam under a beam condition used for processing a sample; (S2) irradiating, with the charged particle beam under the beam condition used for processing the sample, the sample including a processing area to be processed with the charged particle beam to acquire an observation image of the sample; (S3) specifying a boundary of the processing area based on luminance information of the acquired observation image; and (S5) adjusting an irradiation position of the charged particle beam such that a boundary portion of the charged particle beam calculated based on the charged particle beam information comes into contact with the specified boundary of the processing area, and processing the sample.

### TECHNICAL FIELD

The present disclosure relates to a sample processing method and a charged particle beam device.

### BACKGROUND ART

PTL 1 describes a technique of thinning a sample of a transmission electron microscope with a focused ion beam. PTL 1 describes “scanning a plurality of lines by an FIB under a predetermined condition, etching a sample, executing, utilizing an SIM image by the processing FIB or a monitoring SEM image, a pattern matching based on a drift correcting mark provided on an upper surface of the sample, measuring a remaining processing width of a thin film on the upper surface of the sample, calculating an average processing amount in one-line scan based on the remaining processing width of the thin film and the number of times of scanning, calculating the number of scan lines necessary for setting the sample to a predetermined width value, and processing the sample to a set thickness”.

PTL 2 describes a focused ion beam device capable of thinning processing. PTL 2 describes that “a storage unit configured to store positional relation between a first processing area set on an observation image of a first sample and a cross-section surface of the first sample, and a processing area setting unit configured to automatically set a second processing area on an observation image of a second sample based on the positional relation read from the storage unit and a position of a cross-section surface of the second sample on the observation image of the second sample are provided”.

Further, PTL 3 describes a technique of restoring a low quality image for localization when preparing a thin sample. PTL 3 describes “irradiating a sample with an ion beam at a low keV setting; generating a low keV ion beam image of the sample based on an emission resultant from the irradiation by the ion beam; applying an image restoration model to the low keV ion beam image of the sample to generate a restored image; localizing the sample within the restored image; and performing, based on the localized sample within the restored image, a low keV milling of the sample with the ion beam”.

### CITATION LIST

### Patent Literature

PTL 1: JP4318962B

PTL 2: JP6207081B

PTL 3: JP 2021-64606A

### SUMMARY OF INVENTION

### Technical Problem

PTL 1 describes a thinning processing technique using a focused ion beam. In the thinning processing technique described in PTL 1, it is necessary to measure a remaining processing width of a thin film on an upper surface of a sample by a scanning ion microscope (SIM) image by a processing focused ion beam (FIB) or a monitoring scanning electron microscope (SEM) image. Therefore, the processing FIB needs to have an image resolution that allows the remaining processing width of the thin film to be recognized. In recent years, a thickness of the thin film has been required to be 10 nm or less. Thus, it is necessary to further lower an acceleration voltage to reduce a processing damage to the sample. With this low acceleration voltage, the image resolution that allows the remaining processing width of the thin film to be recognized cannot be obtained. In the thinning processing technique described in PTL 1, since the processing FIB requires the image resolution that allows the remaining processing width of the thin film to be recognized, there is a problem that the acceleration voltage cannot be lowered to an acceleration voltage required in recent years.

PTL 2 describes a device equipped with a technique for maintaining quality uniformity by a simpler operation in thinning processing using a focused ion beam. In the technique described in PTL 2, a senior engineer registers setting conditions in advance when preparing a thin sample, and uses information thereof for processing. Therefore, the senior engineer needs to register sample preparation information. Thus, unless there is information on a senior engineer, it is difficult for an immature engineer with poor experience and skill to perform accurate processing.

PTL 3 describes a technique of preparing a thin piece used in a transmission electron microscope based on an FIB image acquired at a low keV. By using the technique described in PTL 3, it is possible to restore a low quality image acquired at low keV with an image restoration algorithm and specify a sample position. This corresponds to a reduction in a beam diameter only on the image. However, since an actual beam diameter remains large, there is a deviation in size from the beam diameter viewed in the processed image. Thus, in order to perform processing with high accuracy, it is necessary to consider the deviation of the beam diameter described above, and advanced technology and experience are required.

An object of the present disclosure is to provide a sample processing method and a charged particle beam device capable of recognizing a boundary of a processing area of a sample even when an acquired observation image has low quality, and capable of processing the sample after adjusting an irradiation position of a charged particle beam such that a boundary portion of the charged particle beam comes into contact with the specified boundary of the processing area.

### Solution to Problem

A sample processing method of the present disclosure is a sample processing method for processing a sample by irradiating the sample with a charged particle beam, the sample processing method including: acquiring beam information including information on a shape and a size of a charged particle beam under a beam condition used for processing the sample; irradiating, with the charged particle beam under the beam condition, the sample including a processing area to be processed with the charged particle beam to acquire an observation image of the sample; specifying a boundary of the processing area based on luminance information of the acquired observation image; and adjusting an irradiation position of the charged particle beam such that a boundary portion of the charged particle beam calculated based on the beam information comes into contact with the specified boundary of the processing area, and processing the sample under the beam condition.

### Advantageous Effects of Invention

According to the present disclosure, it is possible to recognize a boundary of a processing area of a sample even when an acquired observation image has low quality, and to process the sample after adjusting an irradiation position of a charged particle beam such that a boundary portion of the charged particle beam comes into contact with the specified boundary of the processing area. As a result, even an unskilled person with no skills can easily and accurately process the sample.

### BRIEF DESCRIPTION OF DRAWINGS

FIG. 1A is an overall schematic view of a charged particle beam device according to Embodiment 1.

FIG. 1B is a hardware block diagram of a control unit according to Embodiment 1.

FIG. 2 is a flowchart and a schematic view illustrating a sample processing method according to Embodiment 1.

FIG. 3 illustrates an acquisition method of ion beam information according to Embodiment 1.

FIG. 4 is a flowchart illustrating a remaining area updating method according to Embodiment 1.

FIG. 5 illustrates a variation in an ion beam shape according to Embodiment 2.

FIG. 6 is an overall schematic view of a charged particle beam device according to embodiment 2.

FIG. 7 illustrates a variation in a beam intensity distribution according to Embodiment 2.

FIG. 8 is an overall schematic view of a charged particle beam device according to Embodiment 3.

FIG. 9 illustrates a GUI display method according to Embodiments 1, 2, and 3.

FIG. 10 illustrates a GUI display method according to Embodiment 4.

### DESCRIPTION OF EMBODIMENTS

In all drawings for illustrating the embodiments, components having the same functions are denoted by the same reference signs, and repeated description thereof may be omitted. The invention is not to be construed as being limited to the description of the embodiments to be described below. Although the invention is defined by the scope of the claims, it will be easily understood by those skilled in the art that the specific configuration can be changed within a range not departing from the idea or spirit of the invention. Although the embodiments described here focus on an ion beam, the embodiments are not limited to an ion beam because the same processing can be performed with an electron beam depending on a material of a sample to be processed.

In order to facilitate understanding of the invention, the position, size, shape, range, or the like of each configuration illustrated in the drawings or the like may not represent the actual position, size, shape, range, or the like. Therefore, the invention is not necessarily limited to the position, size, shape, range, or the like disclosed in the drawings or the like.

In the present description, a component represented in a single form includes a plurality of forms unless otherwise clearly described in the context.

Hereinafter, embodiments will be described with reference to the drawings.

### Embodiment 1

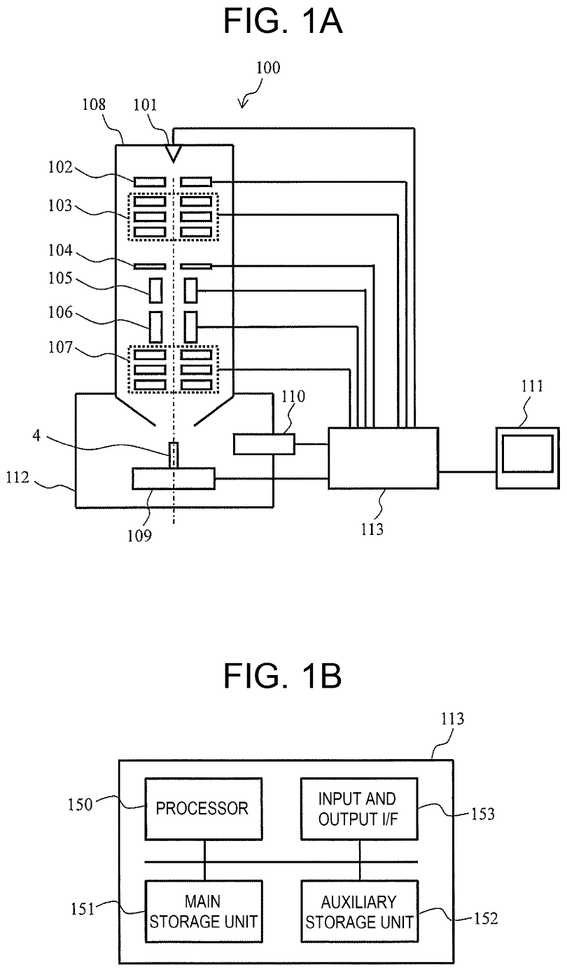

A charged particle beam device 100 and a sample processing method according to Embodiment 1 will be described with reference to FIGS. 1A, 1B, 2, 3, and 4.

### Charged Particle Beam Device 100

FIG. 1A is an overall schematic view of the charged particle beam device 100 according to Embodiment 1. The charged particle beam device 100 of Embodiment 1 is a focused ion beam (FIB) device that irradiates a focused ion beam. The charged particle beam device 100 includes an ion beam column 108 including an ion source 101 that emits an ion beam, an extraction electrode 102 that extracts the ion beam from the ion source 101, a condenser lens 103 that focuses the ion beam, a movable diaphragm 104 that changes a beam current and a beam diameter by restricting the ion beam passing through an aperture, an aligner/stigma electrode 105 that corrects an optical path of the ion beam such that the optical path passes through a center of an objective lens 107 and corrects astigmatism of the ion beam, a deflector 106 that scans the ion beam on a sample 4, and the objective lens 107 that focuses the ion beam on the sample. An optical system of the charged particle beam device 100 includes at least one of the condenser lens 103, the movable diaphragm 104, the aligner/stigma electrode 105, the deflector 106, or the objective lens 107, and irradiates a sample with an ion beam.

Further, the charged particle beam device 100 includes a stage 109 on which the sample 4 is placed, a secondary particle detector 110 that detects secondary particles generated from the sample 4 by irradiating the sample 4 with an ion beam, and a display unit 111 that displays an image created from a signal detected by the secondary particle detector 110. Further, the charged particle beam device 100 includes a vacuum chamber 112 that houses the ion beam column 108, the stage 109, and the secondary particle detector 110. Further, the charged particle beam device 100 includes a control unit 113 that controls the ion beam column 108, the stage 109, the secondary particle detector 110, and the display unit 111.

The charged particle beam device 100 can etch the sample 4 into various shapes by irradiating the sample 4 with the focused ion beam and scanning the sample 4 in any shape.

Secondary particles are emitted from the sample 4 irradiated with the ion beam. A part of the emitted secondary particles is detected by the secondary particle detector 110. The control unit 113 creates an image of the sample 4 from the signal detected by the secondary particle detector 110 and displays the image on the display unit 111.

The control unit 113 executes each processing related to the sample processing method. As a matter of course, an operator can perform the processing without relying on the control unit 113.

### Control Unit 113

FIG. 1B is a hardware block diagram of the control unit 113 according to Embodiment 1. The control unit 113 includes a processor 150, a main storage unit 151, an auxiliary storage unit 152, and an input and output interface (I/F) 153. The processor 150 is a central processing unit that controls an operation of each unit of the control unit 113. The processor 150 is, for example, a central processing unit (CPU), a digital signal processor (DSP), or an application specific integrated circuit (ASIC). The processor 150 loads a program (for example, a program related to the sample processing method) stored in the auxiliary storage unit 152 in a work area of the main storage unit 151 in an executable manner. The main storage unit 151 stores a program executed by the processor 150, data processed by the processor 150, and the like. The processor 150 executes a program loaded in the main storage unit 151 to execute processing related to the sample processing method. The main storage unit 151 is, for example, a flash memory and a random access memory (RAM). The auxiliary storage unit 152 stores various programs and various kinds of data. The auxiliary storage unit 152 stores, for example, an operating system (OS), various programs, various tables, and the like. The auxiliary storage unit 152 is a solid state drive (SSD) device, a hard disk drive (HDD) device, or the like. The ion beam column 108, the stage 109, the secondary particle detector 110, the display unit 111, input devices such as a keyboard and a mouse (not illustrated), and the like are communicably connected to the input and output I/F 153.

### Sample Processing Method

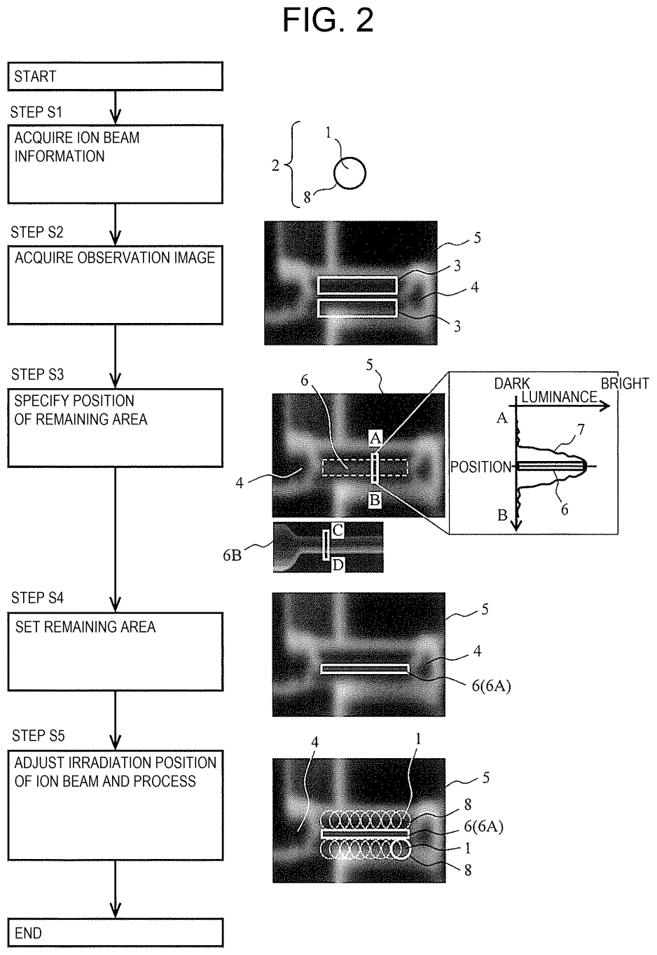

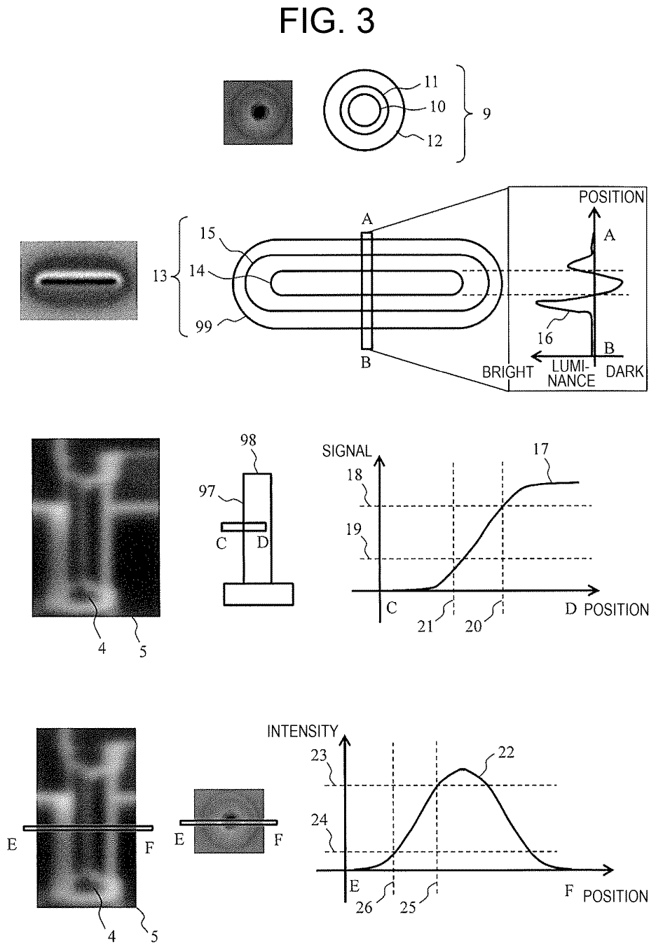

FIG. 2 is a flowchart and a schematic view illustrating a sample processing method according to Embodiment 1. FIG. 3 illustrates an acquisition method of ion beam information according to Embodiment 1. Next, the sample processing method and the acquisition method of ion beam information 2 according to Embodiment 1 will be described with reference to FIGS. 2 and 3. Each step of the flowchart in FIG. 2 is executed by the control unit 113 that executes a program related to the sample processing method.

### Step S1: Acquisition of Ion Beam Information 2

First, as step S1 of FIG. 2, the control unit 113 acquires the ion beam information 2 including information on a shape and a size (for example, a beam diameter) of an ion beam 1 under a beam condition used for processing a sample before processing the sample. A method for acquiring the shape and the size of the ion beam 1 is not limited to the following description. The shape of the ion beam 1 may be acquired by irradiating the sample with the ion beam 1 and acquiring the resulting shape on the sample, or may be acquired without irradiating the sample with the ion beam 1 if the shape is known in advance. Since the size of the ion beam 1 changes depending on a condition of the charged particle beam device 100 and an environment in which the charged particle beam device 100 is placed, the size of the ion beam 1 is acquired by irradiating the sample with the ion beam 1 and acquiring the resulting size on the sample. An acquisition timing of the ion beam information 2 is not limited to immediately before the sample is processed with the ion beam 1. If the ion beam information 2 is acquired by performing spot processing, line processing, cross processing, or the like prior to the time of processing, it is possible to reduce an influence of temporal changes, such as focus fluctuation. However, for example, when a plurality of the same processing steps are intermittently performed, it is difficult to achieve high throughput if the ion beam information 2 is acquired each time immediately before processing (in real time). In recent years, a stabilization technique of the ion beam 1 has progressed, and even when the ion beam information 2 is acquired only at the time of beam adjustment (daily adjustment) performed on the day of processing, for example, the influence of temporal changes in the ion beam 1 used for processing has become a negligible level. For example, depending on the ion source, the ion beam 1 can operate stably for several tens of hours. Therefore, instead of acquiring the ion beam information 2 immediately before the processing (in real time) for each processing in the intermittent processing, for example, when a thin film sample for a transmission electron microscope is prepared, the ion beam information 2 may be acquired before all the processing steps related to the preparation of one sample treated as one set of processing, or may be acquired before all the processing steps to be performed on the day treated as one set of processing. In the present disclosure, the ion beam information 2 is acquired at an optimum timing when a balance between achieving the high throughput and reducing the influence of temporal changes in the ion beam 1 used for processing is struck.

A boundary portion 8 of the ion beam 1 is defined by an intensity distribution of the ion beam 1 or an edge detection method. As illustrated in FIG. 3, the boundary portion 8 of the ion beam 1 is obtained through spot processing 9, at least one line processing 13, or a beam profile 17 by a knife-edge method. The reason why a plurality of means are prepared is that the optimum definition varies depending on a device to be used, desired processing, and the sample 4. Which is optimal may be confirmed by experiment in advance.

The spot processing 9 is performed in three areas: a hole 10, an edge 11, and a halo 12. The boundary portion 8 of the ion beam 1 obtained through the spot processing 9 is a boundary of the hole 10.

The line processing 13 is performed in three areas: a line width 14, an edge 15, and a flare 99. The boundary portion 8 of the ion beam 1 obtained through the line processing 13 is a boundary of the line width 14, and is obtained from a profile 16 indicating an intensity distribution of the ion beam 1 between A and B in the figure crossing the line processing 13.

The boundary portion 8 of the ion beam 1 obtained from the beam profile 17 by the knife-edge method is determined by using a sample 98 having an edge portion 97 and acquiring a width of a beam crossing the edge portion 97 substantially perpendicular to the edge portion 97 from a change in contrast at the edge portion 97. In the case of a circular beam, the width of the beam crossing the edge portion 97 is a beam diameter. The width of the beam crossing the edge portion 97 substantially perpendicular to the edge portion 97 is a distance between a High signal 18 and a Low signal 19 of the beam profile 17 by the knife-edge method, and is a value obtained by subtracting a Low position 21 from a High position 20. The minimum required information of the boundary portion 8 of the ion beam 1 is the width of the beam in a direction substantially perpendicular to a processed cross section or a thin film. Thus, a direction of the edge portion 97 may be aligned with a direction of a cross section or a thin film to be processed. An observation image 5 in FIG. 3 is an observation image of the thin film sample 4. The direction of the edge portion 97 of the sample 98 is aligned with the direction of the thin film, and the beam profile 17 by the knife-edge method between C and D of the edge portion 97 is acquired. Optimal values of the High signal 18 and the Low signal 19 vary depending on a device to be used, desired processing, the sample 4, and the like. Thus, it is confirmed in advance by experiment what percentage the optimum High signal 18 and Low signal 19 represent of a maximum signal intensity. For example, when the acceleration voltage is 5 kV or less, the High signal 18 is 70% of the maximum signal intensity, and the Low signal 19 is 30% of the maximum signal intensity in many cases.

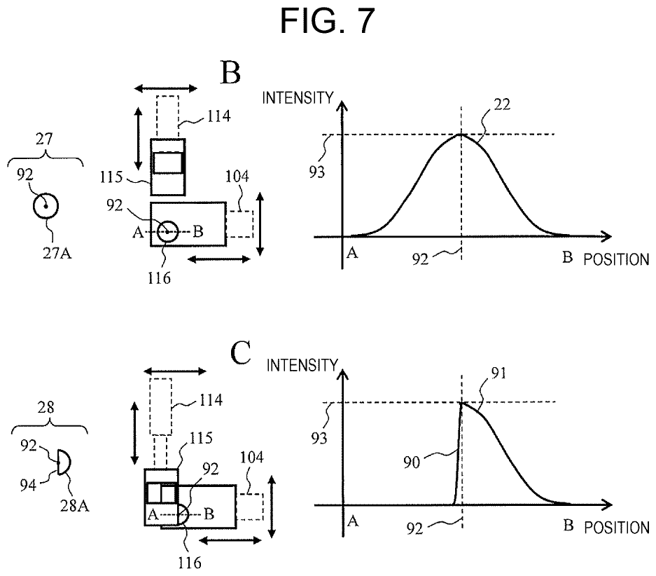

When a Gaussian-like beam intensity distribution 22 is obtained, the boundary portion 8 of the ion beam 1 in one direction has a value obtained by subtracting a Low position 26 from a High position 25, which is a distance between a High signal 23 and a Low signal 24. The value is a width of a beam in one direction, and is a beam diameter in the case of a circular beam. The beam intensity distribution 22 is an intensity distribution of the ion beam 1 at a line A-B in B of FIG. 7. The observation image 5 in FIG. 3 is an observation image when the sample 4 is a thin film. In the minimum required beam intensity distribution 22, the one direction is a direction substantially perpendicular to a direction of the processed cross section or the thin film, that is, an E-F direction in the example of FIG. 3. Optimal values of the High signal 23 and the Low signal 24 vary depending on a device to be used, desired processing, the sample 4, and the like. Thus, it is confirmed in advance by experiment what percentage the optimum High signal 23 and Low signal 24 represent of a maximum beam intensity.

The boundary portion 8 of the ion beam 1 may be determined using a combination of any two or more of the methods described above. Furthermore, in the case of a projection beam, the boundary portion 8 can be calculated based on a size and a reduction ratio of a mask mounted on the movable diaphragm 104 projected onto the sample 4.

### Step S2: Acquisition of Observation Image

In step S2 of FIG. 2, the control unit 113 irradiates, with the ion beam 1 under the beam condition (the beam condition of the ion beam 1 used for processing the sample 4), the sample 4 including a processing area 3 to be processed with the ion beam 1, and acquires the observation image 5 of the sample 4. When the observation image 5 of the sample 4 including the processing area 3 is acquired with an ion beam with a high acceleration voltage of, for example, 30 kV having a good image resolution, the shape of the sample 4 can be clearly recognized, and a high-quality image with high contrast can be obtained. Using the high-quality image may seem advantageous, but when the beam conditions of the ion beam 1 for acquiring the observation image 5 of the sample 4 and the ion beam 1 used for processing are different, the following problem arises. When the sample 4 is a thin film, a thickness of the thin film is required to be 10 nanometers or less. Since the required film thickness is reduced, a thickness of a damaged layer on a sample surface generated during the processing by the ion beam 1 needs to be reduced as compared with the related art. The thickness of the damaged layer can be reduced as the acceleration voltage of the ion beam decreases. Thus, particularly in the case of finish processing, the ion beam 1 used for processing has employed a low acceleration voltage, for example, of 2 kV or less. When the beam conditions of the ion beam 1 for acquiring the observation image 5 of the sample 4 and the ion beam 1 used for processing are different, it is necessary to perform processing in consideration of an axial deviation between the beams and a difference in the position and size of the boundary portion 8 of the ion beam 1. As the required film thickness becomes smaller, the required processing accuracy becomes higher, and thus an unfavorable influence caused by the difference has become more pronounced. Thus, an unskilled person with no skills cannot easily perform processing. If the observation image 5 of the sample 4 including the processing area 3 is acquired with the ion beam 1 used for processing, the unfavorable influence can be reduced.

### Step S3: Specifying Position of Desired Area to be Left (Remaining Area)

In step S3 of FIG. 2, the control unit 113 acquires luminance information 7 of an area 6 to be left unprocessed (hereinafter, referred to as the remaining area 6), and specifies a position of the remaining area 6. Accordingly, the boundary of the processing area 3 is specified. When acquiring the luminance information 7, the control unit 113 sets a position for acquiring the luminance information 7. The position for acquiring the luminance information 7 may be set according to a user instruction, may be set by a prediction model that predicts the position of the remaining area 6, or may be set by pattern matching of the observation image 5.

### Step S4: Setting Desired Area to be Left (Remaining Area)

In step S4 of FIG. 2, the control unit 113 sets the remaining area 6 at the position specified based on the luminance information 7. A shape and a size of the remaining area 6 are set in advance, and the control unit 113 sets the remaining area 6 having the shape and size set in advance at the specified position. A beam size of the ion beam 1 increases as the acceleration voltage decreases, and the observation image 5 is of such low quality that the shape of the sample 4, for example, an edge portion of the thin film cannot be sufficiently recognized. As the quality of the observation image 5 becomes lower, it becomes more difficult for the operator to recognize, for example, the edge portion of the thin film from the observation image 5. For example, in the case of a thin film, the thickness of the thin film is reduced, the beam size is increased, and the quality of the observation image 5 becomes lower. Therefore, a thin film portion does not appear as an image including a bright edge portion, a dark planar portion, and a bright edge portion when viewed in a direction from C to D as in an SIM image 6B acquired with a high acceleration FIB, but appears as one thick bright line as in the observation image 5. The inventors have found that when a profile of the luminance information 7 is acquired by crossing the bright line-like thin film portion from A to B, a peak position of the profile is approximately at a center of the thin film. When the shape and the size of the remaining area 6 are known, the remaining area 6 can be set even with a low quality image by matching a center of the remaining area 6 (a quadrangle 6A in the example of FIG. 2) with the peak position of the profile of the luminance information 7. When the remaining area 6 is displayed superimposed on the observation image 5, the operator can visually recognize the remaining area 6 even in the low quality image.

A detector used to acquire the luminance information may be a secondary electron detector, a backscattered electron detector, an EDS detector, or a detector obtained by combining two or more of these detectors. Since a deviation in luminance may occur depending on the position of the detector, calibration is performed in advance and confirmation is performed.

### Step S5: Adjustment of Irradiation Position of Ion Beam

In step S5 of FIG. 2, the control unit 113 adjusts an irradiation position of the ion beam 1 such that the boundary portion 8 of the ion beam 1 calculated based on the ion beam information 2 acquired in advance comes into contact with the boundary of the remaining area 6 (the boundary of the processing area 3). The ion beam 1 under the beam condition, which is subjected to position adjustment, is irradiated onto the sample to process the sample. Even when the observation image 5 is a low quality image, the remaining area 6 can be recognized, and the boundary portion 8 of the ion beam 1 of the ion beam 1 used for processing can also be recognized, and thus anyone can implement highly accurate processing. Since the remaining area 6 and the boundary portion 8 of the ion beam 1 used for processing can be specified, a processing sequence of steps S1 to S5 can be easily automated.

In addition, when the control unit 113 displays the remaining area 6 superimposed on the observation image 5 in step S4, and further displays the boundary portion 8 (a circle in the example of FIG. 2) of the ion beam 1 used for processing superimposed on the observation image 5 in step S5, the operator can accurately set a scanning position or a scanning area of the ion beam 1 used for processing by visual observation even in the low quality image.

### Remaining Area Updating Method

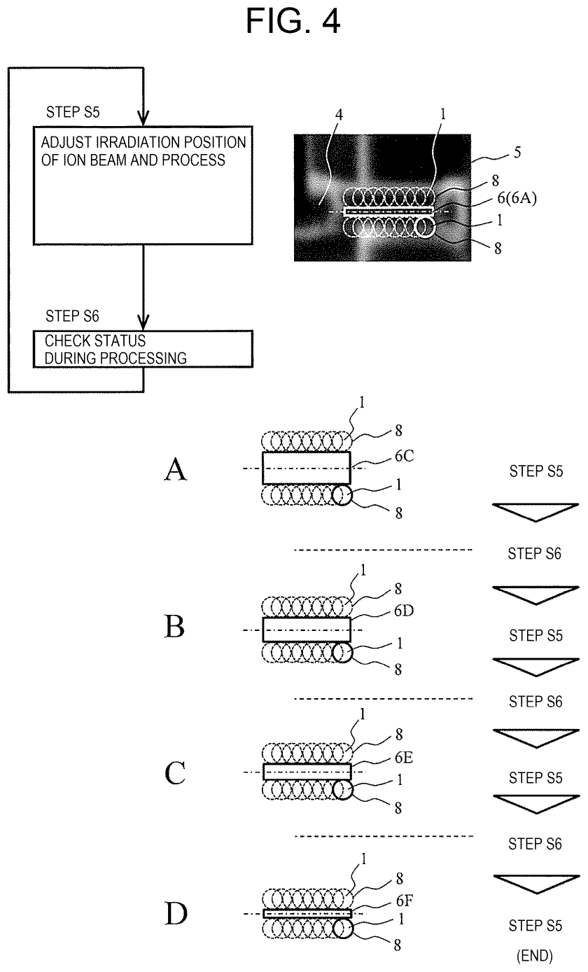

FIG. 4 is a flowchart illustrating a remaining area updating method according to Embodiment 1. Since the processing is divided into a plurality of steps, a plurality of remaining areas 6 may be provided. This is effective when it is desired to check a status during processing. In the updating method, a checking step during processing in step S6 is added to a subsequent stage of step S5 described above. FIG. 4 illustrates an example in which the sample 4 is a thin film, the remaining area 6 is the quadrangle 6A, and step S6 of checking the status during processing is added.

### Step S6: Checking Status During Processing

A short side of the quadrangle 6A corresponds to the thickness of the thin film. There are four remaining areas 6, with a first remaining area 6C being the thickest (A in FIG. 4), and the thickness decreasing progressively for a second remaining area 6D (B in FIG. 4), a third remaining area 6E (C in FIG. 4), and a fourth remaining area 6F (D in FIG. 4). The processing progresses in the order of A in FIG. 4→B in FIG. 4→C in FIG. 4→D in FIG. 4. The operation of step S5 is repeated in each of A, B, C, and D of FIG. 4. The operation of step S6 is repeated between A and B, between B and C, and between C and D in FIG. 4. The charged particle beam device 100 can quantitatively calculate and grasp a one-line processing amount with the ion beam 1 used for processing under a predetermined condition. The completion of processing is determined based on the one-line processing amount and a desired total processing amount. The one-line processing amount may be measured in advance using a standard sample and multiplied by a correction coefficient depending on the material. In addition, the measurement may be performed during the processing of the sample 4 that is actually being processed.

### Effects of Embodiment 1

In Embodiment 1, even when the acquired observation image 5 is a low quality image, the boundary (the remaining area 6) of the processing area 3 of the sample 4 can be recognized, and the boundary portion 8 of the ion beam 1 of the ion beam 1 used for processing can also be recognized. Accordingly, by using the charged particle beam device 100 and the sample processing method according to Embodiment 1, anyone can process a sample with high accuracy.

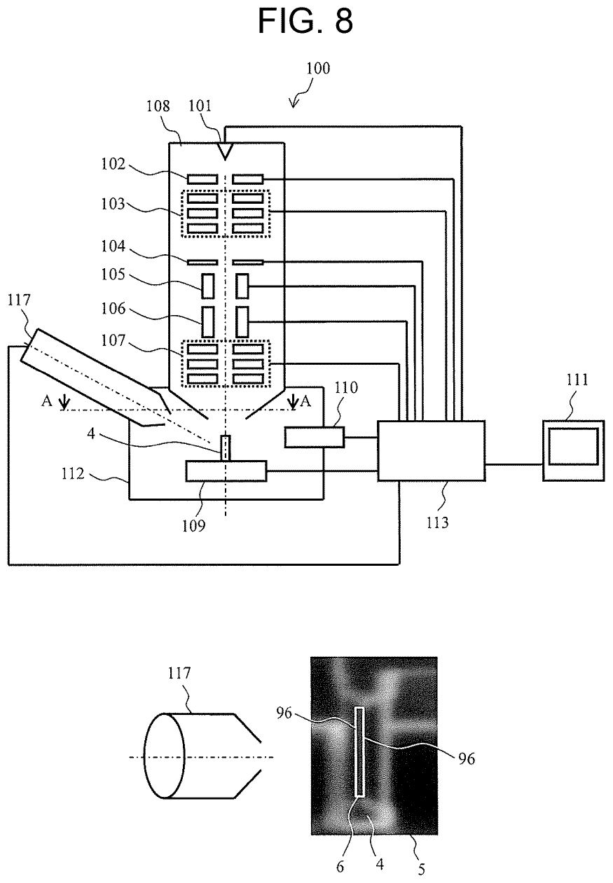

Further, in Embodiment 1, since the boundary of the processing area 3 can be specified even with an existing column (the ion beam column 108) without using a column with improved low-acceleration resolution or an electron beam column 117 of FIG. 8 to be described later, an increase in cost can be prevented.

### Embodiment 2

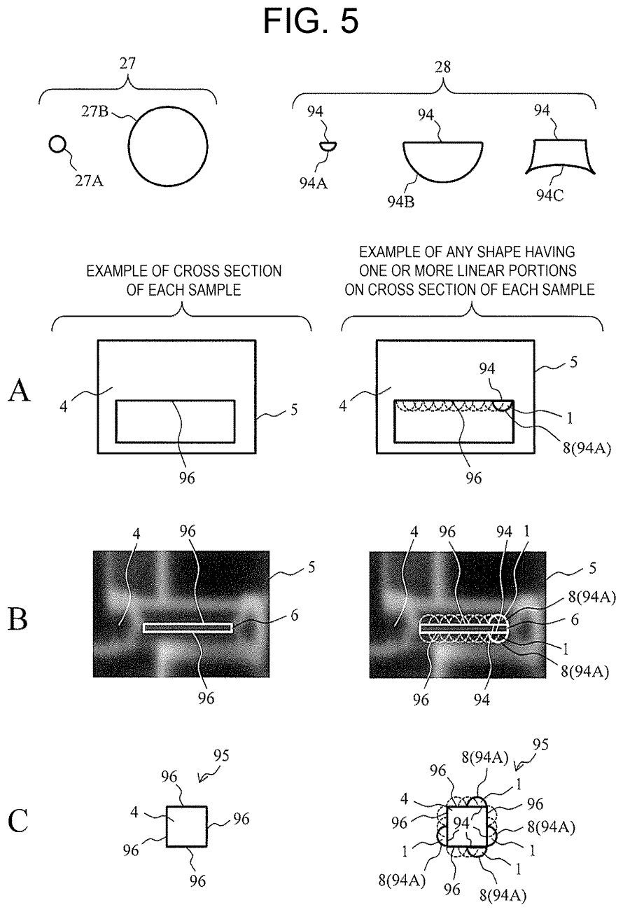

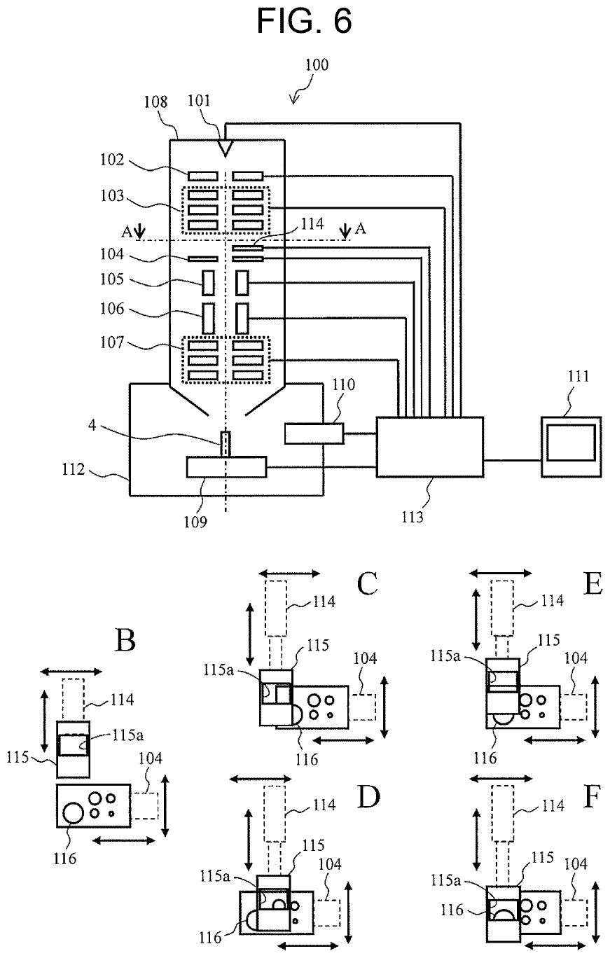

Next, Embodiment 2 will be described with reference to FIGS. 5, 6, and 7. In FIGS. 5 and 6, the same reference numerals as those in FIGS. 2 to 4 denote the same components, and therefore, repeated descriptions are omitted. FIG. 5 illustrates a variation in an ion beam shape according to Embodiment 2. FIG. 6 is an overall schematic view of a charged particle beam device according to Embodiment 2.

As illustrated in FIG. 5, a beam shape of the ion beam 1 used for processing with which the sample 4 is irradiated is a circular shape 27 or any shape 28 having one or more linear portions 94. The circular shape 27 is a spot beam 27A or a projection beam 27B of a circular mask. Any shape 28 having one or more linear portions 94 is a shape 94A obtained by shielding the spot beam 27A, a shape 94B obtained by shielding the projection beam 27B of the circular mask, a shape 94C obtained by shielding a projection beam of a quadrangular mask, or the like. In Embodiment 2, the spot beam 27A or the projection beam 27B is shielded such that the linear portion 94 passes through substantially the center of the spot beam 27A or the projection beam 27B. Since a beam intensity of the spot beam 27A or the projection beam 27B increases toward the center thereof, an intensity of the linear portion 94 also increases. By performing processing with the linear portion 94 having the high beam intensity, a surface in contact with the sample can be sharply processed.

The irradiation position of the ion beam 1 is adjusted such that the linear portion 94 of the ion beam 1 having any shape 28 comes into contact with a processing surface of the sample 4. Specifically, the linear portion 94 of the ion beam 1 is substantially parallel to a cross section 96 to be processed of the sample 4, the cross section 96 of a thin film, the cross section 96 of a quadrangular pillar 95, or a combination of any two or more thereof, and is adjusted to be in contact with the cross section 96. FIG. 5 illustrates an example in which the linear portion 94 obtained by shielding 28A the spot beam of any shape 28 having one or more linear portions 94 is adjusted to be substantially parallel to the cross section 96 obtained by performing cross-section processing on the planar portion as illustrated in A of FIG. 5, an example in which the linear portion 94 is adjusted to be substantially parallel to each of two cross sections 96 of the thin film as illustrated in B of FIG. 5, and an example in which the linear portion 94 is adjusted to be substantially parallel to each of four cross sections 96 of the quadrangular pillar 95 as illustrated in C of FIG. 5.

Since the circular shape 27 can be formed without providing an additional mechanism in the ion beam column 108, an increase in cost can be prevented.

As illustrated in FIG. 6, the charged particle beam device 100 of Embodiment 2 further includes a movable shielding portion 114 provided in the ion beam column 108 to form any shape 28 having at least one or more linear portions 94. The movable shielding portion 114 moves a shielding portion 115 according to an instruction from the control unit 113. The shielding portion 115 shields a part of the ion beam 1 used for processing, which passes through the movable diaphragm 104. As illustrated in FIG. 6, for example, a circular aperture 116 is formed in the movable diaphragm 104. The ion beam column 108 switches between shielded and unshielded states using the shielding portion 115 during processing, observation, or both thereof.

The shielding portion 115 that matches a desired beam shape is attached to the movable shielding portion 114. The shielding portion 115 has a plurality of linear portions and forms the linear portions 94 in various directions. The shielding portion 115 has a shielding plate formed of straight lines, an opening having a linear portion, or a combination of both. In FIG. 6, a quadrangular opening 115a is provided in the shielding portion 115 to generate any shape 28 having one or more linear portions 94. The operation of the movable shielding portion 114 is controlled by the control unit 113. As illustrated in B of FIG. 6, the control unit 113 forms a beam having the circular shape 27 by retracting the shielding portion 115 so as not to overlap the movable diaphragm aperture 116. As illustrated in C of FIG. 6, the control unit 113 controls the movement of the shielding portion 115 to shield a left half of the movable diaphragm aperture 116, thereby generating a beam having a linear portion on the left side. As illustrated in D of FIG. 6, the control unit 113 controls the movement of the shielding portion 115 to shield a right half of the movable diaphragm aperture 116, thereby generating a beam having a linear portion on the right side. As illustrated in E of FIG. 6, the control unit 113 controls the movement of the shielding portion 115 to shield an upper half of the movable diaphragm aperture 116, thereby generating a beam having a linear portion on the upper side. As illustrated in F of FIG. 6, the control unit 113 controls the movement of the shielding portion 115 to shield a lower half of the movable diaphragm aperture 116, thereby generating a beam having a linear portion on the lower side. By controlling the movement of the shielding portion 115 in this manner, a beam shape having four types of linear portions can be generated. Note that B to F in FIG. 6 are diagrams viewed from an A-A direction in FIG. 6.

Any shape 28 having one or more linear portions 94 can make edge sharpness of the beam intensity distribution higher than a skirt (a flare) of the circular beam by the linear portion 94 by providing anisotropy. As illustrated in A, B, and C of FIG. 5, by making the linear portion 94 of the beam shielding the spot beam substantially parallel to the cross section 96 to be processed, the sharpness of the processed cross section 96 can be further increased.

FIG. 7 is a variation in the beam intensity distribution of Embodiment 2. As illustrated in FIG. 7, the beam intensity distribution 22 of the beam having the circular shape 27 is a Gaussian distribution. When processing is performed with an ion beam having the circular shape 27, cross-section processing is performed at a tail portion of this Gaussian distribution.

### Effects of Embodiment 2

Any shape 28 (a semicircle in FIG. 7) having one or more linear portions 94 is formed by performing control such that the linear portion of the shielding portion 115 is positioned at an approximate center 92 of an optical axis of the ion beam 1 passing through the movable diaphragm aperture 116 of the movable diaphragm 104. A beam intensity distribution 91 obtained by shielding a left half from the approximate center 92 has an edge 90 where the inclination of the beam intensity is steep. The beam intensity distribution 91 is an intensity distribution of the ion beam 1 at a line A-B in C of FIG. 7. By performing cross-section processing at the edge 90 of the beam intensity distribution 91, sharpness of the processed cross section is improved. Further, a peak 93 of the beam intensity distribution 91 is near the center of the linear portion 94 of the ion beam 1 used for processing. Accordingly, since the cross-section processing can be performed at the peak 93 of the beam intensity distribution 91, the throughput is improved. As a result, the processing throughput is improved while the sharpness of the processed cross section 96 remains high.

In the case of the circular shape 27, in consideration of the beam diameter, adjustment is made so that the edge of the beam having the circular shape 27 comes to the remaining area 6, and then processing is performed. On the other hand, in the case of any shape 28 having one or more linear portions 94, adjustment is made so that the linear portion of the beam having one or more linear portions 94 comes to the remaining area 6, and then processing is performed.

### Embodiment 3

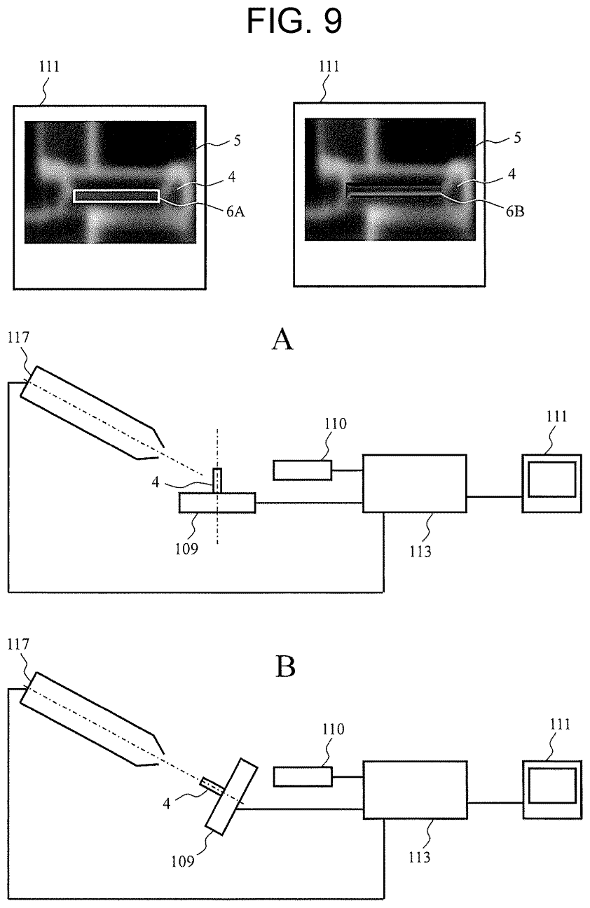

Next, Embodiment 3 will be described with reference to FIGS. 8 and 9. In FIGS. 8 and 9, the same reference numerals as those in FIGS. 2 to 7 denote the same components, and therefore, repeated descriptions are omitted.

FIG. 8 is an overall schematic view of the charged particle beam device 100 according to Embodiment 3. As illustrated in FIG. 8, the charged particle beam device 100 includes the electron beam column 117 at a position where a processed cross section of the sample 4 can be observed. The operation of the electron beam column 117 is controlled by the control unit 113. The observation image 5 in FIG. 8 is an example in which the sample 4 is a thin film. The electron beam column 117 is disposed obliquely above the cross section 96 of the thin film in an opposing direction such that the cross section 96 and an upper surface of the thin film can be imaged by the ion beam column 108 during processing of the cross section of the thin film. When the cross section 96 on an opposite side of the thin film is imaged, the stage 109 is rotated by 180 degrees. The lower diagram in FIG. 8 is a diagram viewed from an A-A direction in FIG. 8.

A processing end point of the sample is determined by an SEM image (a scanning electron microscope image) and an STEM image (a scanning transmission electron microscope image) captured by the electron beam column 117 during processing of the sample 4, an electron-induced X-ray signal detected during processing of the sample 4, or a combination of any two or more thereof. The processing end point is determined by a cross-sectional structure appearing in the cross section 96 of the sample 4, a specific element signal appearing in the cross section 96, a thickness when the sample 4 is a thin film, or a combination of two or more thereof.

When a position determined to be the processing end point is before the remaining area that has been initially set, the remaining area is set again and the processing is resumed. The SEM (the electron beam column 117) is an essential component in order to determine the end point using a high-resolution image with less physical damage than observation with an ion beam. Thus, in the sample preparation involving the end point determination as described above, the device configuration of FIG. 8 is used.

### Effects of Embodiment 3

Providing the electron beam column 117 is particularly effective for semiconductor analysis. For example, when a new structure of a semiconductor circuit is examined, the processing can be stopped when a desired structure appears, so that a risk of losing the desired structure due to over-processing can be reliably avoided. While the description here focuses on the structure, attention may alternatively be given to elements included in the desired structure. For example, when defect analysis is performed, it is absolutely necessary to avoid losing the desired structure due to over-processing on a defective portion that happens to appear. When the cross section 96 is continuously observed by the electron beam column 117 until a defect appears continuously or intermittently, the above risk can be reliably prevented. When the STEM image (the scanning transmission electron microscope image) is used, the presence or absence of a defect can be checked from a state in which the defective portion is still in a bulk. When the electron-induced X-ray signal is acquired, for example, an impurity element can be specified. These are advantages unique to the electron beam column 117, which cannot be obtained by the ion beam column 108.

Providing the electron beam column 117 is also effective in preparing a thin-film sample for a transmission electron microscope. When the sample 4 is a thin film, the thickness of the thin film can be measured by directly measuring an upper end width of the thin film by secondary electrons, or by backscattered electrons, transmitted electrons, or electron-induced X-ray signals from the thin film, or a combination of any two or more thereof. When the upper end width of the thin film is directly measured by the ion beam column 108, there is a risk that an upper end of the sample is damaged or disappears due to a sputtering phenomenon. However, when the upper end width of the thin film is directly measured by the electron beam column 117, this risk can be avoided.

### GUI Display Method

FIG. 9 illustrates a GUI display method according to Embodiments 1, 2, and 3. The sample 4 in FIG. 9 is a thin film. As illustrated in FIG. 9, the observation image 5 and information indicating the boundary of the processing area 3 are displayed on the display unit 111 in a superimposed manner. The information indicating the boundary of the processing area 3 is, for example, the quadrangle 6A indicating the boundary of the remaining area 6, the SIM image 6B (a high-resolution image) acquired in advance under a condition of a high-acceleration FIB with high image resolution, for example, an acceleration voltage of 30 kV before processing, or the SEM image (a high-resolution image) acquired in advance before processing by the electron beam column 117. When the electron beam column 117 is obliquely mounted as in Embodiment 3, there are two methods for acquiring an SEM image. The first method is a method of observing an upper surface of the thin film as the sample 4 with the stage 109 in a horizontal state as in a state A of FIG. 9. In the SEM image as it is, since the film thickness is captured to be smaller than that of the actual thin film, it is necessary to correct an inclination angle of the electron beam column 117 to an actual aspect ratio. The second method is a method of tilting the stage 109 until an upper surface of the thin-film sample 4 faces the electron beam column 117 as in a state B of FIG. 9. Thereafter, an SEM image is acquired. In this case, an SEM image can be acquired at an actual aspect ratio.

When the operator mainly performs work by visual observation, by displaying the SIM image 6B or the SEM image acquired by the high-acceleration FIB with high image resolution in the remaining area 6, it is possible to reduce psychological anxiety caused by the remaining area 6 not being clearly visible.

### Embodiment 4

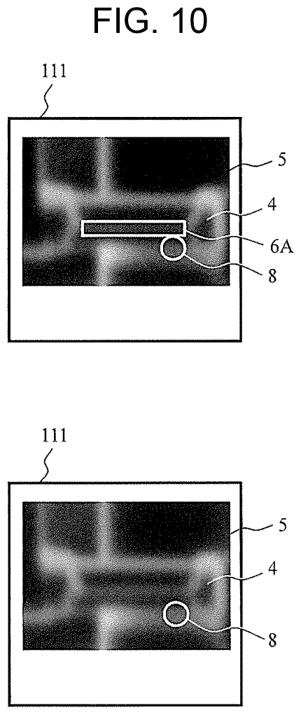

Next, Embodiment 4 will be described with reference to FIG. 10. In FIG. 10, the same reference numerals as those in FIGS. 1 to 9 denote the same components, and therefore, repeated descriptions are omitted.

FIG. 10 illustrates a GUI display method according to Embodiment 4. FIG. 10 is effective when the operator mainly performs work by visual observation. As illustrated in FIG. 10, the boundary portion 8 of the ion beam 1 is also superimposed on the observation image 5 and displayed on the display unit 111. The boundary portion 8 of the ion beam 1 may be displayed simultaneously with the remaining area 6, or only the boundary portion 8 of the ion beam 1 may be displayed alone. FIG. 10 is an example in which the remaining area is the quadrangle 6A.

### Effects of Embodiment 4

By displaying the boundary portion 8 of the ion beam 1, it is possible to reduce psychological anxiety due to the boundary portion 8 of the ion beam 1 not being visible.

### Embodiment 5

A flow of preparing a sample to be used in the transmission electron microscope involves first performing rough processing to remove most of the sample with the ion beam column 108, and then finishing a thin film. When a film thickness of a remaining sample piece is measured immediately before the thin film is processed, the processing area can be set easily and the processing can be performed efficiently. Therefore, for example, the rough processing is performed at a high acceleration voltage of 30 kV, and thus, after the rough processing is completed, the film thickness is measured using a beam condition used in the rough processing. Since the sample may be damaged at the acceleration voltage of 30 kV, the film thickness may be measured using the electron beam column 117 when the processing is performed using the charged particle beam device 100 equipped with the ion beam column 108 and the electron beam column 117 as illustrated in FIG. 8.

When processing is started, a processing area is set using the luminance information and the beam information described in the above embodiments and the measured film thickness after the rough processing, and then the processing is started. The film thickness measurement after processing is not limited to the rough processing. If necessary, the film thickness may be measured even after intermediate processing performed after the rough processing, or the film thickness may be measured even after finish processing performed after the intermediate processing.

For example, when the remaining area is a center of the sample piece, a thickness of the processing area can be calculated by subtracting a half size of the remaining area from a half size of the film thickness acquired above. By using this value for setting the processing area, it is possible to set a processing frame without protruding from the sample piece even when the sample piece appears as one thick bright line in the low quality image.

### Modification

The present disclosure is not limited to the above embodiments and includes various modifications. For example, the above embodiments are described in detail to describe the present disclosure in an easy-to-understand manner and are not necessarily limited to including all the described configurations. A part of a configuration according to a certain embodiment can be replaced with a configuration according to another embodiment, and a configuration according to another embodiment can be added to a configuration according to a certain embodiment. In addition, another configuration can be added to, deleted from, or replaced with a part of a configuration of each embodiment.

For example, in Embodiments 1 to 5 described above, an example in which a sample is processed by irradiating the sample with a focused ion beam has been described, but the present disclosure is not limited to a device that processes a sample with a focused ion beam, and may be a charged particle beam device that processes a sample with an electron beam. In addition, the above embodiments mainly describe processing using a low acceleration voltage, but there is also a case where it is difficult to obtain a resolution capable of allowing a processing area and a remaining area to be recognized even with a large current or a projection beam. Also in this case, it is possible to set the processing area by using the same method.

Although the electron beam column 117 is provided in Embodiment 3, the electron beam column 117 may not be provided in the charged particle beam device of the present disclosure as in Embodiment 1 and the like. Even when the electron beam column 117 used to acquire an SEM image for monitoring is not additionally mounted, processing positioning can be performed even with the existing column as in Embodiment 1, and thus an increase in cost can be prevented.

In Embodiment 1, an example in which the control unit 113 executes each step in FIGS. 2 and 4 has been described, but the control unit 113 does not need to execute all steps S1 to S6. For example, the control unit 113 may execute step S1, step S2, step S5, and step S6 that require direct data communication with the charged particle beam device 100, and another computer system (for example, a cloud computer or an on-premise server) may execute other steps S3 and S4.

### Reference Signs List

1: ion beam used for processing
2: ion beam information
3: processing area
4: sample
5: observation image
6: remaining area
6A: quadrangle
6B: SIM image acquired with high acceleration FIB
6C: first remaining area
6D: second remaining area
6E: third remaining area
6F: fourth remaining area
7: luminance information
8: boundary portion of ion beam
9: spot processing
10: hole
11: edge
12: halo
13: line processing
14: line width
15: edge
99: flare
16: profile
17: beam profile by knife-edge method
18: High signal
19: Low signal
20: High position
21: Low position
22: beam intensity distribution
23: High signal
24: Low signal
25: High position
26: Low position
27: circular shape
27A: spot beam
27B: projection beam
28: any shape
90: edge of beam intensity distribution
91: beam intensity distribution obtained by shielding half from center
92: approximate center of optical axis
93: peak of beam intensity distribution
94: linear portion
95: pillar
96: cross section
97: edge portion
98: sample with edge portion
100: charged particle beam device
101: ion source
102: extraction electrode
103: condenser lens
104: movable diaphragm
105: aligner/stigma electrode
106: deflector
107: objective lens
108: ion beam column
109: stage
110: secondary particle detector
111: display unit
112: vacuum chamber
113: control unit
114: movable shielding portion
115: shielding portion
116: movable diaphragm aperture
117: electron beam column
150: processor
151: main storage unit
152: auxiliary storage unit
153: input and output I/F

1-15. (canceled)

16. A sample processing method for processing a sample by irradiating the sample with a charged particle beam, the sample processing method comprising:
acquiring beam information including information on a shape and a size of a charged particle beam under a beam condition used for processing the sample;
irradiating the sample, which includes a processing area to be processed with the charged particle beam and a remaining area to be left unprocessed, with the charged particle beam under the beam condition to acquire an observation image of the sample;
specifying a boundary between the processing area and the remaining area by a luminance profile crossing the remaining area based on luminance information of the acquired observation image; and
setting an irradiation position of the charged particle beam such that a boundary portion of the charged particle beam calculated based on the beam information comes into contact with the specified boundary, and processing the sample at the set irradiation position under the beam condition.

17. The sample processing method according to claim 16, wherein
setting a position for acquiring the luminance information includes
setting the position according to a user instruction,
setting the position by a prediction model configured to predict the position of the remaining area, or
setting the position by pattern matching of the observation image.

18. The sample processing method according to claim 16, wherein
the beam information is calculated based on a beam intensity distribution obtained by spot processing on a sample with the charged particle beam, a beam intensity distribution obtained by line processing on a sample with the charged particle beam, a beam intensity distribution obtained by irradiating a sample having an edge with the charged particle beam, or a combination of at least two of the intensity distributions.

19. The sample processing method according to claim 16, wherein
the charged particle beam used for processing the sample has a circular shape or a shape having one or more linear portions.

20. The sample processing method according to claim 19, further comprising:
setting, with a shielding portion having a linear portion that shields the charged particle beam, the shape of the charged particle beam used for processing the sample to the shape having one or more linear portions.

21. The sample processing method according to claim 20, further comprising:
moving the shielding portion such that the linear portion of the shielding portion is located substantially at a center of the charged particle beam.

22. The sample processing method according to claim 19, wherein
adjusting the irradiation position of the charged particle beam includes adjusting the irradiation position of the charged particle beam such that the linear portion of the charged particle beam comes into contact with a processing surface of the sample.

23. The sample processing method according to claim 16, further comprising:
determining a processing end point of the sample based on an electron microscope image captured during processing of the sample, an electron-induced X-ray signal detected during processing of the sample, or a combination thereof.

24. The sample processing method according to claim 23, wherein
determining the processing end point of the sample includes determining the processing end point of the sample based on a cross-sectional structure of the sample appearing in the electron microscope image, an element indicated by the X-ray signal, a thickness of the sample, or a combination of at least two or more thereof.

25. The sample processing method according to claim 16, further comprising:
displaying the observation image and information indicating the boundary of the processing area in a superimposed manner.

26. The sample processing method according to claim 16, further comprising:
acquiring a high-resolution image of the sample with a higher image resolution than the observation image before processing the sample; and
displaying the observation image and the high-resolution image arranged at the boundary of the processing area in a superimposed manner.

27. The sample processing method according to claim 16, further comprising:
displaying the observation image and at least one of information indicating the boundary of the processing area or information indicating the boundary portion of the charged particle beam in a superimposed manner.

28. A charged particle beam device that irradiates a sample with a charged particle beam to process the sample, the charged particle beam device comprising:
a charged particle beam source configured to emit the charged particle beam;
an optical system configured to irradiate the sample with the charged particle beam emitted from the charged particle beam source; and
a control unit, wherein
the control unit is configured to
acquire beam information including information on a shape and a size of a charged particle beam under a beam condition used for processing the sample,
control the charged particle beam to be irradiated under the beam condition onto the sample including a processing area to be processed with the charged particle beam and a remaining area to be left unprocessed, and acquire an observation image of the sample,
specify a boundary between the processing area and the remaining area by a luminance profile crossing the remaining area based on luminance information of the acquired observation image, and
set an irradiation position of the charged particle beam such that a boundary portion of the charged particle beam calculated based on the beam information comes into contact with the specified boundary, and perform control to process the sample at the set irradiation position under the beam condition.

29. The sample processing method according to claim 16, wherein the beam condition is a beam condition under which an image resolution does not allow a remaining processing width of a thin film to be recognized.

30. The sample processing method according to claim 16, wherein the beam information is acquired by irradiating the sample with the beam before processing the sample.

31. The sample processing method according to claim 16, wherein a thickness of the remaining area is smaller than a beam size of the charged particle beam.
